(19) United States
(12) Patent Application Publication
(10) Pub. No.: US 2024/0351570 A1
(43) Pub. Date: Oct. 24, 2024

(54) Power Supply System Having A Shut-Off Circuit

(71) Applicant: Sumitomo Wiring Systems, Ltd., Yokkaichi-shi (JP)

(72) Inventors: Jessica L. Thompson, Farmington Hills, MI (US); Robert Grooms, Farmington Hills, MI (US); Vibhor Singh, Farmington Hills, MI (US)

(21) Appl. No.: 18/303,377

(22) Filed: Apr. 19, 2023

(51) Int. Cl. B60W 20/00; B60L 3/04; B60L 50/60; H03K 17/56

(52) U.S. Cl. CPC B60W 20/00; B60L 3/04; B60L 50/60; H03K 17/56

(57) ABSTRACT

A power distribution box having a shut-off circuit for turning off an intelligent power device is provided. The power distribution box is configured for a system wherein a motor control module is configured to send instructions to a motor which is powered by a battery. The shut-off circuit is interposed between a relay and the intelligent power device and is operable to turn off the intelligent power device when an error is detected. Accordingly, the intelligent power device may be turned off even when the operating conditions of the intelligent power device are within the tolerance built into the intelligent power device itself. Further, errors in signals generated in other devices may be processed to turn off the intelligent power device.

### TECHNICAL FIELD

This disclosure relates to a power supply system and in particular a shut-off circuit for a power supply system.

### BACKGROUND

With reference now to FIG. 1, a schematic diagram of a control system 500 utilizing an Intelligent Power Device (IPD) 502 for providing power to a motor 504 is provided. The IPD 502 includes protection circuits, such as an overcurrent or thermal detection module, which allows the IPD 502 to shut down and protect itself. The IPD 502 is controlled by a controller 506 such as a motor control module which receives and transmits signals, e.g. commands to and from a computer processing unit 508. The IPD 502 is configured to process errors, e.g. overcurrent or open load, from the controller 506 and will shut down so as to protect itself. However, errors in the control system 500 that do not originate from the controller 506 may cause the motor 504 to deteriorate or otherwise fail. Accordingly, it may be desirable to turn off power to the motor 504 even when the controller 506 instructs the IPD to provide power to the motor so as to protect the system (e.g. the motor control system).

For illustrative purposes, the control system 500 is provided in the context of a parking system of an automotive vehicle. The automotive vehicle includes a plurality of vehicle systems which are controlled by a vehicle system control module (e.g. Controller), such as windshield wipers, turn signals and the like. The Controller 506 may also include a Hybrid Powertrain Control Module (HPCM) 506a configured to control the operation of a Park By Wire Motor (PBWM) 504. For illustrative purposes, a single controller 506 is shown as having a single HPCM 506a, but it may be that the control system 500 includes a plurality of control modules that are separate and distinct modules for controlling a specific motor. The controller 506 is coupled to a Computer Processing Unit (CPU) 508 of a power distribution box 510.

The power distribution box 510 further includes a HPCM relay 512. The HPCM 506a sends a signal to both the HPCM Relay 512 and the CPU 508 to power the motor 504 (in this case, the PBWM). When the HPCM Relay 512 is turned on, power from the battery 514 is supplied to the IPD 502, and when the CPU 508 receives instructions from the Control Module 506 to supply power to the motor 504, the CPU 508 instructs the IPD 502 to turn on, thus power from the battery 514 is supplied to the motor 504.

There may be instances where it is desirable to turn off power to the motor 504 despite a signal from the HPCM 506a to provide power to the motor 504, such as in the case of over-voltage, under-voltage, over-current or under-current conditions. For instance, in an over-voltage condition of the PBWM 504, the overvoltage may result in damage to the motor 504 or the control system 500. In such an event, it is desirable to shut off the IPD 502 even though the HPCM 512 may transmit a signal to operate, that is, the HPCM Relay 512 is turned on.

Accordingly, it remains desirable to have a control system with a shut-off circuit configured to turn off the IPD, even when a motor control module instructs the IPD to operate, so as to prevent a motor and/or the IPD from being damaged.

### SUMMARY

In one aspect, a shut-off circuit is provided. The shut-off circuit is configured for use in a control system having a motor control module, a relay, an intelligent power device, a computer processing unit and a motor. The motor control module transmits commands to actuate the relay and the intelligent power device. The intelligent power device is coupled to a battery, to provide power to the motor.

The shut-off circuit includes a first transistor, a second transistor, a first input and a second input. The first transistor is connected in series to the second transistor at a first node. The second transistor has an emitter connected to a ground, and the first transistor and the second transistor are interposed between the relay and the intelligent power device.

The first input is connected in series with the first transistor, and a second input is connected in series with the second transistor. The motor control module transmits a first signal to the first transistor so as to turn on the first transistor, wherein power is supplied to the intelligent power device, turning on the intelligent power device. The computer processing unit transmits a second signal to the second transistor so as to turn on the second transistor, wherein power is directed to ground, turning off the intelligent power device.

Accordingly, the intelligent power device may be turned off even when the operating conditions of the intelligent power device are within the tolerance built into the intelligent power device.

In one aspect, the first transistor may be a PNP transistor and the second transistor may be an NPN transistor.

In another aspect, the first signal has a lower voltage than the second signal.

In yet another aspect, the shut-off circuit further includes a first resistor and a second resistor connected in parallel at a second node, the second node interposed between the first transistor and the first input.

In yet another aspect, the shut-off circuit further includes a first capacitor connected in parallel with both the first resistor and first transistor. The first capacitor interposed between the first resistor and the first transistor.

In yet another aspect, the shut-off circuit further includes a third resistor and a second resistor connected in parallel with each other at a third node, the third node interposed between the second input and the second transistor.

In yet another aspect, the shut-off circuit further includes a fifth resistor interposed between the first transistor and the first node.

In yet another aspect, the shut-off circuit further includes a first diode interposed between the second node and the first input.

In yet another aspect, the shut-off circuit further includes a second diode interposed between the first node and the intelligent power device, the second diode in parallel with the second transistor and the intelligent power device.

Provided herein is also a power distribution box for a vehicle system. The vehicle system includes a control module disposed outside of the power distribution box. The control module is configured to control the operation of a motor. The vehicle system further includes a battery for supplying power to the motor. The power distribution box includes a relay, an intelligent power device, a computer processing unit, and a shut-off circuit. The relay is electrically coupled to the battery and the control module. The control module is configured to turn on and off the relay. The intelligent power device is interposed between the relay and the motor, and the relay and the intelligent power device disposed along a first electrical path. The computer processing unit is configured to transmit information to the control module.

The shut-off circuit is disposed on the first electrical path and interposed between the relay and the intelligent power device. The shut-off circuit includes a first transistor, a second transistor, a first input and a second input. The first transistor is connected in series to the second transistor at a first node. The second transistor includes an emitter connected to a ground. The first transistor and the second transistor are interposed between the relay and the intelligent power device. The first input is connected in series with the first transistor and the second input is connected in series with the second transistor.

The control module transmits a low input signal to the first transistor so as to turn on the first transistor directing an enable signal to the intelligent power device, turning on the intelligent power device, wherein the intelligent power device connects the motor to the battery so as to power the motor. The computer processing unit transmits a second signal to the second transistor so as to turn on the second transistor wherein power is directed to ground, turning off the intelligent power device

Accordingly, the power distribution box may be implemented in a vehicle system having a motor, wherein the intelligent power device may be turned off even when the operating conditions of the intelligent power device are within the tolerance built into the intelligent power device.

In one aspect, the first transistor is a PNP transistor and the second transistor is an NPN transistor.

In one aspect of the power distribution box, the first signal has a lower voltage than the second signal.

In one aspect, the power distribution box further includes a first resistor and a second resistor connected in parallel at a second node. The second node is interposed between the first transistor and the first input.

In one aspect, the power distribution box further includes a first capacitor connected in parallel with both the first resistor and first transistor, and the first capacitor is interposed between the first resistor and the first transistor.

In one aspect, the power distribution box further includes a third resistor and a second resistor connected in parallel with each other at a third node, and the third node is interposed between the second input and the second transistor.

In one aspect, the power distribution box further includes a fifth resistor interposed between the first transistor and the first node.

In one aspect, the power distribution box further includes a first diode interposed between the second node and the first input.

In one aspect, the power distribution box further includes a second diode interposed between the first node and the intelligent power device, the second diode in parallel with the second transistor and the intelligent power device.

In yet another aspect, the vehicle system is a park by wire system and the motor is a park by wire motor.

### DESCRIPTION OF DRAWINGS

FIG. 1 is an illustrative schematic view of a conventional control system.

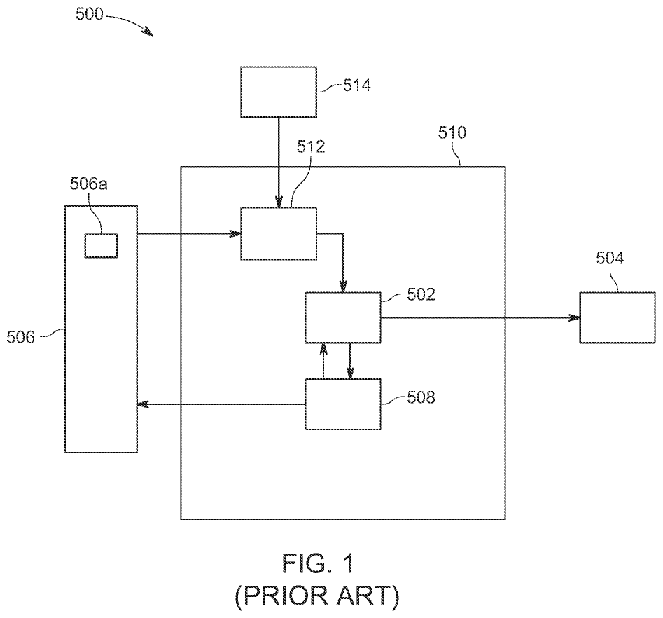

FIG. 2 is an illustrative schematic view of a control system according to one or more aspects described herein.

FIG. 3 is a schematic view of the shut-off circuit shown in FIG. 2 in a normal operating condition.

FIG. 4 is an illustrative schematic view of the shut-off circuit shown in FIG. 2 during an electrical error in the control system.

### DETAILED DESCRIPTION

A power distribution box having a shut-off circuit for turning off an intelligent power device is provided. The power distribution box is configured for a system wherein a motor control module is configured to send instructions to a motor which is powered by a battery. The power distribution box includes a relay, an intelligent power device, a computer processing unit and a shut-off circuit. The motor control module transmits commands to actuate the relay. When the relay is turned on, the intelligent power device is also turned on so as to provide power to the motor.

The shut-off circuit is interposed between the relay and the intelligent power device and is operable to turn off the intelligent power device when an error is detected. As used herein, an “error” refers to a condition relating to an over-voltage, under-voltage, over-current, under-current condition or overheating condition. Accordingly, the intelligent power device may be turned off even when the operating conditions of the intelligent power device are within the tolerance built into the intelligent power device itself. Further, errors in signals generated in other devices may be processed to turn off the intelligent power device.

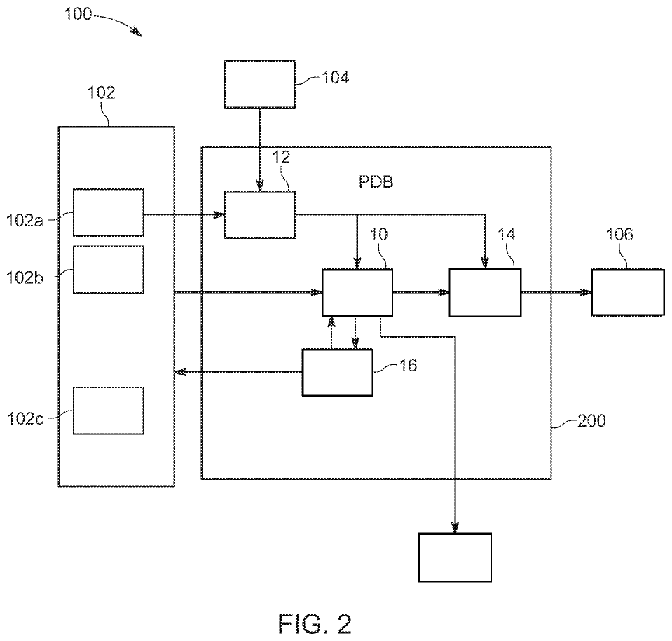

With reference now to FIG. 2, a shut-off circuit 10 is provided. The shut-off circuit 10 is configured for use in a hybrid powertrain control system 100 having a motor control module 102 configured to make connect a battery 104 to a motor 106. In one aspect, the shut-off circuit 10 is disposed in a power distribution box 200. The power distribution box 200 includes a relay 12, an intelligent power device 14 and a computer processing unit 16. The motor control module 102 transmits commands to actuate the relay 12 and the intelligent power device 14. In particular, the command to turn on the intelligent power device 14 is transmitted from the motor control module 102 through the relay 12. When the relay 12 and the intelligent power device 14 are turned on, a power supply path is formed from the battery 104 to the motor 106.

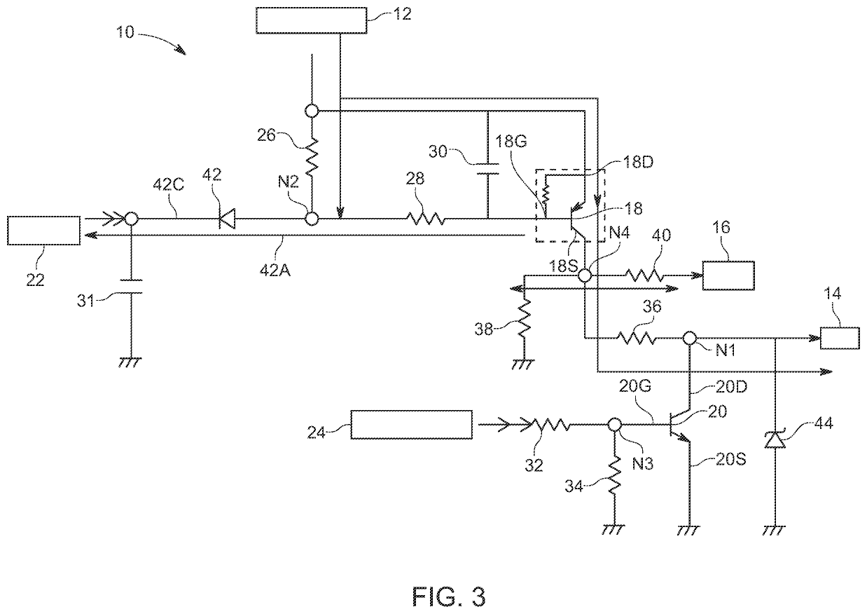

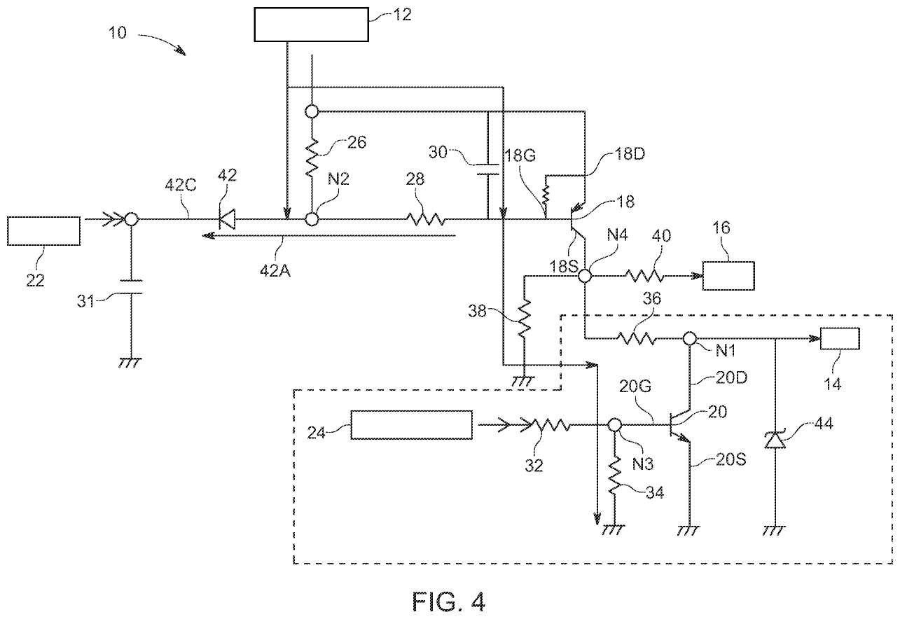

With reference now to FIG. 3, a depiction of the shut-off circuit 10 according to one or more aspects disclosed herein is provided. The shut-off circuit 10 includes a first transistor 18, a second transistor 20, a first input 22 and a second input 24. The first transistor 18 is disposed along a first electrical path (shown in dashed lines in FIG. 3) which forms a path of power from the relay 12 to the intelligent power device 14. The second transistor 20 is configured to form a second electrical path (shown in dashed lines in FIG. 4) which forms a path of power from the shut-off circuit 10 to ground.

The first transistor 18 and the second transistor 20 are disposed on the second electrical path and are connected to each other in series at a first node (N1). The first transistor 18 and the second transistor 20 are interposed between the relay 12 and the intelligent power device 14. The first transistor 18 includes a first emitter, a first base 18G and a first collector 18S. The second transistor 20 includes a second collector 20D, a second base 20G and a second emitter 20S.

The first emitter 18D of the first transistor 18 is connected to the relay 12, and the first base 18G of the first transistor 18 is connected to the first input 22. The first collector 18S of the first transistor 18 is connected to the second collector 20D of the second transistor 20. The second base 20G of the second transistor 20 is connected to the second input 24. The second emitter 20S of the second transistor 20 is connected to ground, thus when the second transistor 20 is turned on, current flowing through the second transistor 20 is grounded. In one aspect, the first transistor 18 may be transistor commonly known as a PNP transistor and the second transistor 20 may be a transistor commonly known as an NPN transistor.

The first input 22 is connected in series with the first transistor 18, and the second input 24 is connected in series with the second transistor 20. The first input 22 is configured to receive a first signal from the motor control module 102 and transmits the first signal to the first transistor 18 so as to turn on the first transistor 18 wherein power is supplied to the motor 106. In instances where the first transistor 18 is a PNP transistor, the first signal is a low voltage signal which is lower than the voltage at the first base 18G of the first transistor 18 as indicated by the directional arrow, thus the first transistor 18 is turned on. The computer processing unit 16 transmits a second signal to the second transistor 20 so as to turn on the second transistor 20, wherein power is directed to ground, turning off the intelligent power device 14.

The first input 22 and the second input 24 is connected to the computer processing unit 16. In one aspect, the motor control module 102 includes a first pin (not shown) for transmitting the first signal and a second pin (not shown) for transmitting the second signal. In one aspect, the first signal is a low signal and the second signal is a high signal, e.g. operable to transmit a low voltage signal and a high voltage signal. Simply put, the first signal has a lower voltage than the second signal. It should be appreciated that the configuration shown in the figures is illustrative and not limiting to the scope of the appended claims. For instance, it may be contemplated that the computer processing unit 16 operates a switch to connect between the first input 22 and the second input 24 wherein a low or a high signal is transmitted based upon the position of the switch.

The shut-off circuit 10 may further include a first resistor 26 and a second resistor 28 connected in parallel at a second node (N2). The second node (N2) is interposed between the first transistor 18 and the first input 22. The first resistor 26 and the second resistor 28 are configured to limit current to the first input 22 and the first transistor 18 respectively.

In one aspect, the shut-off circuit 10 may further include a first capacitor 30 connected in parallel with both the first resistor 26 and the first transistor 18. The first capacitor 30 is interposed between the first resistor 26 and the first transistor 18 and may be configured to filter noise from reaching the first transistor 18. For instance, the first capacitor 30 may be configured to filter noise, such as a low current high-frequency noise, from reaching the first transistor 18.

In yet another aspect, shut-off circuit 10 may include a second capacitor 31 connected in parallel with the first transistor 18 and in series with the second resistor 28. The second capacitor 31 is interposed between the first input 22 and the first transistor 18 and may be configured to filter noise from reaching the first transistor 18. For instance, the second capacitor 31 may be configured to filter noise, such as a low current high-frequency noise, from reaching the first transistor 18.

The shut-off circuit 10 may further include a third resistor 32 and a fourth resistor 34 connected in parallel with each other at a third node (N3). The third node (N3) is interposed between the second input 24 and the second transistor 20. The third resistor 32 and the fourth resistor 34 function as a voltage and current divider. Voltage and current from the second input 24 is divided between the third resistor 32 and the fourth resistor 34. In one aspect, the third resistor 32 and the fourth resistor 34 are the same, in which case the voltage and current from the second input 24 are divided equally. However, it should be appreciated that the third resistor 32 and the fourth resistor 34 may be different, thus the voltage and current are not divided equally.

The shut-off circuit 10 may further include a fifth resistor 36 interposed between the first transistor 18 and the first node (N1). The fifth resistor 36 provides a voltage drop from the first transistor 18 to the intelligent power device 14. In one aspect, the first resistor 26 is connected in parallel to a sixth resistor 38 and a seventh resistor 40 at a fourth node (N4). One end of the sixth resistor 38 is connected to the fourth node (N4) and the other end of the sixth resistor 38 is connected to ground. One end of the seventh resistor 40 is connected to the fourth node (N4) and the other end of the seventh resistor 40 is connected to the computer processing unit 16. The fifth resistor 36, sixth resistor 38 and seventh resistor 40 form a voltage and current divider regulating voltage and current transmitted to the intelligent power device 14 and the computer processing unit 16. It should be appreciated that the computer processing unit 16 processes a signal from the seventh resistor 40 to determine that power is being delivered to the intelligent power device 14. The signal from the seventh resistor 40 may also be processed by the intelligent power device 14 to determine an error.

The fourth node (N4) is interposed between the first transistor 18 and the first node (N1). Voltage from the first transistor 18 is divided between the fifth resistor 36, the sixth resistor 38 and the seventh resistor 40. In one aspect, the fifth resistor 36, the sixth resistor 38 and the seventh resistor 40 are the same, in which case the voltage and current from the first transistor 18 are divided equally. However, it should be appreciated that the first resistor 26 and the second resistor 28 may be different, thus the voltage and current are not divided equally.

The shut-off circuit 10 may further include a first diode 42 interposed between the second node (N2) and the first input 22. The first diode 42 includes a cathode 42C and an anode 42A. The cathode 42C is oriented towards the first input 22 and the anode 42A is oriented towards the first base 18G of the first transistor 18. Thus, the first diode 42 is configured to prevent a high current from flowing from the first input 22. As used herein, a high current refers to a signal having a current that is greater than a predetermined current. Such a feature helps protect the first transistor 18 from damage.

The shut-off circuit 10 may further include a second diode 44 interposed between the first node (N1) and the intelligent power device 14. The second diode 44 is in parallel with the second transistor 20 and the intelligent power device 14. In one aspect, the second diode 44 is a Zener diode and is operable to limit the voltage to the intelligent power device 14.

In operation, the motor control module 102 transmits a first signal to the first transistor 18 so as to turn on the first transistor 18 wherein power is supplied to the motor 106 along the first electrical path as shown in FIG. 3. The computer processing unit 16 processes the signal from the fifth resistor 36 to determine if an error exists, wherein upon detection of an error, the computer processing unit 16 transmits the second signal to the second transistor 20 so as to turn on the second transistor 20 forming the second electrical power path wherein power is directed to ground, as shown in FIG. 4. As no power is transmitted to the intelligent power device 14, the intelligent power device 14 is turned off, protecting the intelligent power device 14 from damage. As such, even though the relay 12 may be turned on, power having an error is prevented from reaching the motor 106 so as to protect the motor 106 from damage.

With reference again to FIG. 2, a power distribution box 200 for a hybrid powertrain control system 100 is provided. The hybrid powertrain control system 100 includes a motor control module 102 configured to control the operation of a motor 106 and a battery 104 for supplying power to the motor 106. For illustrative purposes, the hybrid powertrain control system 100 is a vehicle system including a hybrid powertrain control module 102a and a park by wire motor 106. The hybrid powertrain control module 102a is programmed with instructions for controlling the operation of the park by wire motor 106. The hybrid powertrain control system 100 may include other control modules (e.g. 102b, 102c) for controlling other motors (not shown), such as a windshield wiper motor. The motor control module 102 transmits instructions to the power distribution box 200 for connecting the motor 106 to the battery 104.

The power distribution box 200 includes a relay 12, an intelligent power device 14, a computer processing unit 16, and a shut-off circuit 10. The relay 12 is electrically coupled to the battery 104 and the hybrid powertrain control module 102a. The hybrid powertrain control module 102a is configured to turn on and off the relay 12.

The hybrid powertrain control module 102a may also transmit signals to the relay 12 for turning on the intelligent power device 14. Accordingly, when the relay 12 is turned on, the signal from the relay 12 is transmitted to the intelligent power device 14, turning on the intelligent power device 14. As such, an electrical connection is made between the battery 104 and the park by wire motor 106, as shown in FIG. 3. It should be appreciated that the motor control module 102 may provide diagnostic information relating to other vehicle systems via control modules 102b, 102c to the power distribution box 200. Accordingly, an error processed by the computer processing unit 16 to turn off the park by wire motor 106a is not necessarily an error processed by the hybrid powertrain control module 102a, but may be from the other motor control modules 102b, 102c.

With reference now to FIG. 3, a depiction of the shut-off circuit 10 according to one or more aspects disclosed herein is provided. The shut-off circuit 10 includes a first transistor 18, second transistor 20, a first input 22 and a second input 24. The first transistor 18 is disposed along a first electrical path which forms a path of power from the relay 12 to the intelligent power device 14 as shown in FIG. 3. The second transistor 20 is configured to form a second electrical path which forms a path of power from the shut-off circuit 10 to ground as shown in FIG. 4.

The first transistor 18 and the second transistor 20 are disposed on the second electrical path and are connected to each other in parallel at a first node (N1). The first transistor 18 includes a first emitter 18D, a first base 18G and a first collector 18S. The second transistor 20 includes a second collector 20D, a second base 20G and a second emitter 20S. The first emitter 18D of the first transistor 18 is connected to the relay 12, and the first base 18G of the first transistor 18 is connected to the first input 22. The second transistor 20 has a source connected to a ground, and the first transistor 18 and the second transistor 20 are interposed between the relay 12 and the intelligent power device 14. The first collector 18S of the first transistor 18 is connected to the second collector 20D of the second transistor 20. The second base 20G of the second transistor 20 is connected to the second input 24. The second emitter 20S of the second transistor 20 is connected to ground. Thus, when the second transistor 20 is turned on, current flowing through the second transistor 20 is grounded. In one aspect, the first transistor 18 may be a transistor commonly known as a PNP transistor and the second transistor 20 may be a transistor commonly known as an NPN transistor.

The first input 22 is connected in series with the first transistor 18, and the second input 24 is connected in series with the second transistor 20. The hybrid powertrain control module 102a transmits a first signal to the first transistor 18 so as to turn on the first transistor 18 wherein power is supplied to the motor 106. The computer processing unit 16 transmits a second signal to the second transistor 20 so as to turn on the second transistor 20 wherein power is directed to ground, turning off the intelligent power device 14.

The first input 22 is connected to the hybrid powertrain control module 102a and the second input 24 is connected to the computer processing unit 16. In one aspect, the hybrid powertrain control module 102a includes a first pin for transmitting the first signal and the computer processing unit 16 includes a second pin for transmitting the second signal. In one aspect, the first signal is a low signal and the second signal is a high signal, e.g. operable to transmit a low voltage signal and a high voltage signal. Simply put, the first signal has a lower voltage than the second signal. It should be appreciated that the configuration shown in the figures is illustrative and not limiting to the scope of the appended claims. For instance, it may be contemplated that the computer processing unit 16 operates a switch to connect between the first input 22 and the second input 24, wherein a low or a high signal is transmitted based upon the position of the switch.

The shut-off circuit 10 may further include a first resistor 26 and a second resistor 28 connected in parallel at a second node (N2). The second node (N2) is interposed between the first transistor 18 and the first input 22. The first resistor 26 and the second resistor 28 are configured to limit current to the first input 22 and the first transistor 18 respectively.

In one aspect, the shut-off circuit 10 may further include a first capacitor 30 connected in parallel with both the first resistor 26 and first transistor 18. The first capacitor 30 is interposed between the first resistor 26 and the first transistor 18 and may be configured to filter noise from reaching the first transistor 18. For instance, the first capacitor 30 may be configured to filter noise such as a low current high-frequency noise from reaching the first transistor 18.

The shut-off circuit 10 may further include a third resistor 32 and a fourth resistor 34 connected in parallel with each other at a third node (N3). The third node (N3) is interposed between the second input 24 and the second transistor 20. The third resistor 32 and the fourth resistor 34 function as a voltage and current divider. Voltage and current from the second input 24 is divided between the third resistor 32 and the fourth resistor 34. In one aspect, the third resistor 32 and the fourth resistor 34 are the same, in which case the voltage and current from the second input 24 are divided equally. However, it should be appreciated that the third resistor 32 and the fourth resistor 34 may be different, thus the voltage and current are not divided equally.

The shut-off circuit 10 may further include a fifth resistor 36 interposed between the first transistor 18 and the first node (N1). The fifth resistor 36 provides a voltage drop from the first transistor 18 to the intelligent power device 14. In one aspect, the first resistor 26 is connected in parallel to a sixth resistor 38 and a seventh resistor 40 at a fourth node (N4). One end of the sixth resistor 38 is connected to the fourth node (N4) and the other end of the sixth resistor 38 is connected to ground. One end of the seventh resistor 40 is connected to the fourth node (N4) and the other end of the seventh resistor 40 is connected to the computer processing unit 16. The fifth resistor 36, sixth resistor 38 and seventh resistor 40 form a voltage and current divider regulating voltage and current transmitted to the intelligent power device 14 and the computer processing unit 16. It should be appreciated that the computer processing unit 16 processes a signal from the seventh resistor 40 to determine that power is being delivered to the intelligent power device 14. The signal from the seventh resistor 40 may also be processed by the intelligent power device 14 to determine an error.

The fourth node (N4) is interposed between the first transistor 18 and the first node (N1). Voltage from the first transistor 18 is divided between the fifth resistor 36, the sixth resistor 38 and the seventh resistor 40. In one aspect, the fifth resistor 36, the sixth resistor 38 and the seventh resistor 40 are the same, in which case the voltage and current from the first transistor 18 are divided equally. However, it should be appreciated that the first resistor 26 and the second resistor 28 may be different, thus the voltage and current are not divided equally.

The shut-off circuit 10 may further include a first diode 42 interposed between the second node (N2) and the first input 22. The first diode 42 includes a cathode 42C and an anode 42A. The cathode 42C is oriented towards the first input 22 and the anode 42A is oriented towards the first base 18G of the first transistor 18. Thus, the first diode 42 is configured to prevent a high current from flowing from the first input 22. As used herein, a high current refers to a signal having a current that is greater than a predetermined current. Such a feature helps protect the first transistor 18 from damage.

The shut-off circuit 10 may further include a second diode 44 interposed between the first node (N1) and the intelligent power device 14. The second diode 44 is in parallel with the second transistor 20 and the intelligent power device 14. In one aspect, the second diode 44 is a Zener diode and is operable to limit the voltage to the intelligent power device 14.

In operation, the hybrid powertrain control module 102a transmits a first signal to the first transistor 18 so as to turn on the first transistor 18 wherein power is supplied to the motor 106. In one aspect, the computer processing unit 16 processes the signal from the fifth resistor 36 to determine if an error exists, wherein upon detection of an error, the computer processing unit 16 transmits the second signal to the second transistor 20 so as to turn on the second transistor 20 which forms the second electrical power path wherein power is directed to ground. As such, even though the relay 12 is turned on, power having an error is prevented from reaching the motor 106 so as to protect the motor 106 from damage.

In another aspect, the computer processing unit 16 processes a signal from the control module, wherein an error from a different vehicle system, such as the windshield wiper or the like, to determine if an error exists. In the event of an error existing in a different vehicle system, e.g. a system other than the hybrid powertrain control system 100, the computer processing unit 16 may transmit the second signal so as to turn on the second transistor 20. In either case, when the second transistor 20 is turned on, no power is transmitted to the intelligent power device 14 and the intelligent power device 14 is turned off. Thus, the power distribution box 200 is configured to not only process errors within a hybrid powertrain but also errors from different vehicle systems to turn off the intelligent power device 14 and protect the park by wire motor 106. Thus, the power distribution box 200 can process an error in a vehicle system which can affect or otherwise damage the park by wire motor 106 to turn off the intelligent power device 14 so as to protect the park by wire motor 106 even if the hybrid powertrain control system 100 is operating under normal conditions, as used herein, the term “normal condition” refers to a condition where an error does not exist.

It should be appreciated that the value and construction of the known elements, such as the first resistor 26, the second resistor 28, the third resistor 32, the fourth resistor 34, the first capacitor 30, the first diode 42, the second diode 44, the first transistor 18 and the second transistor 20 are beyond the scope of the disclosure and such components may be modified and adapted for use herein based the operating conditions of the system, e.g. the capacity of the battery 104, the current and voltage thresholds of the motor 106 and the like.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

We claim:

1. A shut-off circuit for use in a control system having a motor control module, a relay, an intelligent power device, a computer processing unit and a motor, the motor control module configured to transmit commands to actuate the relay and the intelligent power device, the intelligent power device coupled to a battery to provide power to the motor, the shut-off circuit comprising:
a first transistor connected in series to a second transistor at a first node, the second transistor having a source connected to a ground, the first transistor and the second transistor interposed between the relay and the intelligent power device;
a first input connected in series with the first transistor; and
a second input connected in series with the second transistor,
wherein the hybrid powertrain control module transmits a first signal to the first transistor so as to turn on the first transistor so as to direct power to the motor, the computer processing unit transmits a second signal to the second transistor so as to turn on the second transistor wherein power is directed to the ground, turning off the intelligent power device.

2. The shut-off circuit as set forth in claim 1, wherein the first transistor is a PNP transistor.

3. The shut-off circuit as set forth in claim 1, wherein the second transistor is an NPN transistor.

4. The shut-off circuit as set forth in claim 1, wherein the first signal has a lower voltage than the second signal.

5. The shut-off circuit as set forth in claim 1, further including a first resistor and a second resistor connected in parallel at a second node, the second node interposed between the first transistor and the first input.

6. The shut-off circuit as set forth in claim 5, further including a first capacitor connected in parallel with both the first resistor and the first transistor, the first capacitor interposed between the first resistor and the first transistor.

7. The shut-off circuit as set forth in claim 1, further including a third resistor and a second resistor connected in parallel with each other at a third node, the third node interposed between the second input and the second transistor.

8. The shut-off circuit as set forth in claim 1, further including a fifth resistor interposed between the first transistor and the first node.

9. The shut-off circuit as set forth in claim 5, further including a first diode interposed between the second node and the first input.

10. The shut-off circuit as set forth in claim 1, further including a second diode interposed between the first node and the intelligent power device, the second diode in parallel with the second transistor and the intelligent power device.

11. A power distribution box for a vehicle system, the vehicle system including a control module configured to control the operation of a motor and a battery for supplying power to the motor, the power distribution box comprising:
a relay electrically coupled to the battery and the control module, the control module configured to turn on and off the relay;
an intelligent power device interposed between the relay and the motor, the relay and the intelligent power device disposed along a first electrical path;
a computer processing unit configured to transmit and receive instructions to and from the control module; and
a shut-off circuit disposed on the first electrical path and interposed between the relay and the intelligent power device, the shut-off circuit including:
a first transistor connected in parallel to a second transistor at a first node, the second transistor having a source connected to a ground, the first transistor and the second transistor interposed between the relay and the intelligent power device;
a first input connected in series with the first transistor; and
a second input connected in series with the second transistor,
wherein the control module transmits a first signal to the first transistor so as to turn on the first transistor so as to direct power to the motor, the computer processing unit transmits a second signal to the second transistor so as to turn on the second transistor wherein power is directed to the ground, turning off the intelligent power device.

12. The power distribution box as set forth in claim 11, wherein the first transistor is a PNP transistor and the second transistor is an NPN transistor.

13. The power distribution box as set forth in claim 11, wherein the first signal has a lower voltage than the second signal.

14. The power distribution box as set forth in claim 11, further including a first resistor and a second resistor connected in parallel at a second node, the second node interposed between the first transistor and the first input.

15. The power distribution box as set forth in claim 14, further including a first capacitor connected in parallel with both the first resistor and the first transistor, the first capacitor interposed between the first resistor and the first transistor.

16. The power distribution box as set forth in claim 11, further including a third resistor and a second resistor connected in parallel with each other at a third node, the third node interposed between the second input and the second transistor.

17. The power distribution box as set forth in claim 11, further including a fifth resistor interposed between the first transistor and the first node.

18. The power distribution box as set forth in claim 14, further including a first diode interposed between the second node and the first input.

19. The power distribution box as set forth in claim 11, further including a second diode interposed between the first node and the intelligent power device, the second diode in parallel with the second transistor and the intelligent power device.

20. The power distribution box as set forth in claim 11, wherein the vehicle system is a park by wire system and the motor is a park by wire motor.
